(19) United States
(12) Patent Application Publication
(10) Pub. No.: US 2014/0238476 A1
(43) Pub. Date: Aug. 28, 2014

(54) PHOTOELECTRIC CONVERSION DEVICE AND MANUFACTURING METHOD THEREOF, AND PHOTOELECTRIC CONVERSION MODULE

(71) Applicants: Hirofumi Konishi, Tokyo (JP); Tsutomu Matsuura, Tokyo (JP); Yusuke Nishikawa, Tokyo (JP); Katsutoshi Sugawara, Tokyo (JP)

(72) Inventors: Hirofumi Konishi, Tokyo (JP); Tsutomu Matsuura, Tokyo (JP); Yusuke Nishikawa, Tokyo (JP); Katsutoshi Sugawara, Tokyo (JP)

(73) Assignee: Mitsubishi Electric Corporation, Chiyoda-ku, Tokyo (JP)

(21) Appl. No.: 14/347,826

(22) PCT Filed: Apr. 10, 2012
(86) PCT No.: PCT/JP2012/059808

§ 371 Date: Mar. 27, 2014

(30) Foreign Application Priority Data
Oct. 27, 2011 (JP) 2011-235783

(51) Int. Cl. H01L 31/0224; H01L 31/18; H01L 31/075

(52) U.S. Cl. CPC H01L 31/022475; H01L 31/075; H01L 31/1884
USPC 136/255; 438/87

(57) ABSTRACT

A photoelectric conversion device in which a substantially intrinsic i-type amorphous hydrogen-containing semiconductor layer, a p-type amorphous hydrogen-containing semiconductor layer, and a first transparent conductive layer are stacked in this order on a first surface of an n-type semiconductor substrate that generates a photogenerated carrier by receiving light, wherein the first transparent conductive layer includes a hydrogen-containing area formed of a transparent conductive material that contains hydrogen and a hydrogen-diffusion suppression area that is present on a side of the p-type amorphous hydrogen-containing semiconductor layer with respect to the hydrogen-containing area and that is formed of a transparent conductive material that does not substantially contain hydrogen, and the hydrogen-diffusion suppression area has a hydrogen concentration distribution in which a hydrogen content on a side of the p-type amorphous hydrogen-containing semiconductor layer is lower than that on a side of the hydrogen-containing area.

### FIELD

The present invention relates to a photoelectric conversion device and a manufacturing method thereof, and a photoelectric conversion module.

### BACKGROUND

In recent years, as photoelectric conversion devices, solar cells using crystalline semiconductors, such as monocrystalline silicon and polycrystalline silicon, have been studied intensively and are practically used. Among these solar cells, a solar cell that has a heterojunction of crystalline silicon and amorphous silicon (a heterojunction solar cell) has attracted attention, because a higher conversion efficiency than that of a conventional crystalline silicon solar cell can be obtained (see, for example, Patent Literatures 1 and 2).

A heterojunction solar cell has a configuration in which in a photovoltaic device configured by successively stacking a monocrystalline semiconductor and a non-monocrystalline semiconductor that have opposite conductivity types, an intrinsic non-monocrystalline semiconductor film having a film thickness of several angstroms to 250 angstroms is interposed between these semiconductors. For example, a heterojunction solar cell that has a configuration in which a substantially intrinsic amorphous silicon layer that contains hydrogen (an i-type amorphous silicon layer) is inserted between an n-type monocrystalline silicon substrate and a p-type amorphous silicon layer that contains hydrogen has been developed.

According to such a heterojunction solar cell, a transparent conductive layer made of Sn-doped indium oxide (ITO: Indium Tin Oxide) is generally formed on a p-type amorphous silicon layer. However, ITO has a high carrier concentration such as an extent of 10²² cm⁻³ and causes an optical absorption loss due to free carrier absorption in a near-infrared region. Therefore, in recent years, a photoelectric conversion device in which a transparent conductive layer made of hydrogen-doped indium oxide (In₂O₃:H) instead of ITO is formed has been proposed (see, for example, Non Patent Literature 1). Because the carrier concentration of In₂O₃:H is lower than that of conventional ITO by about two to three orders of magnitude and the mobility of In₂O₃:H is higher, suppression of an optical absorption loss is expected.

### CITATION LIST

### Patent Literatures

Patent Literature 1: Japanese Patent No. 2132527
Patent Literature 2: Japanese Patent No. 2614561

### Non Patent Literature

Non Patent Literature 1: T. Koida et al, “Hydrogen-doped In203 transparent conducting oxide films prepared by solid-phase crystallization method”, JOURNAL OF APPLIED PHYSICS, 2010, Vol. 107, P33514

### SUMMARY

### Technical Problem

However, a photoelectric conversion device that uses In₂O₃:H as a transparent conductive film has the following problems. That is, because of heating during or after film formation of In₂O₃:H, hydrogen radicals in a film formation chamber atmosphere or hydrogen contained in In₂O₃:H may diffuse to a p-type amorphous silicon layer, so that the activation rate of boron (B) serving as a dopant for the p-type amorphous silicon layer is reduced. This causes a reduction in an internal electric field of a solar cell and a bad contact of In₂O₃:H and the p-type amorphous silicon layer, so that the output characteristics of the solar cell are degraded.

The present invention has been achieved in view of the above problems, and an object of the present invention is to provide a photoelectric conversion device that suppresses degradation in output characteristics of a solar cell due to diffusion of hydrogen during or after film formation of a transparent conductive layer that contains hydrogen and a manufacturing method thereof, and a photoelectric conversion module.

### Solution to Problem

In order to achieve the above object, a photoelectric conversion device according to the present invention is a photoelectric conversion device in which a substantially intrinsic semiconductor layer, a p-type semiconductor layer, and a transparent conductive layer are stacked in this order on a first surface of an n-type semiconductor substrate that generates a photogenerated carrier by receiving light, wherein the transparent conductive layer includes a hydrogen-containing area formed of a transparent conductive material that contains hydrogen and a hydrogen-diffusion suppression area that is present on a side of the p-type semiconductor layer with respect to the hydrogen-containing area and that is formed of a transparent conductive material that does not substantially contain hydrogen, and the hydrogen-diffusion suppression area has a hydrogen concentration distribution in which a hydrogen content on a side of the p-type semiconductor layer is lower than a hydrogen content on a side of the hydrogen-containing area.

### Advantageous Effects of Invention

According to the present invention, because a hydrogen-diffusion suppression area is provided between a p-type semiconductor layer and a hydrogen-containing area, it is possible to suppress diffusion of hydrogen radicals present in a film formation chamber atmosphere of the hydrogen-containing area or hydrogen in the hydrogen-containing area to a valence-controlled amorphous semiconductor layer. As a result, in the process during or after film formation of a hydrogen-containing transparent conductive film, degradation in output characteristics of a solar cell can be suppressed.

### BRIEF DESCRIPTION OF DRAWINGS

FIG. 1 is a cross-sectional view of the schematic configuration of a photoelectric conversion device according to an embodiment of the present invention.

FIG. 2-1 is a schematic cross-sectional view of an example of a procedure of a manufacturing method of the photoelectric conversion device according to the present embodiment (Part 1).

FIG. 2-2 is a schematic cross-sectional view of an example of the procedure of the manufacturing method of the photoelectric conversion device according to the present embodiment (Part 2).

FIG. 3 is a diagram of an example of the states of first transparent conductive layers of photoelectric conversion cells according to an Example and Comparative examples and the evaluation results thereof.

### DESCRIPTION OF EMBODIMENTS

A photoelectric conversion device and a manufacturing method thereof, and a photoelectric conversion module according to embodiments of the present invention will be explained below in detail with reference to the accompanying drawings. The present invention is not limited to the embodiments. The cross-sectional views of the photoelectric conversion device used in the following embodiments are only schematic and the relationships between thicknesses and widths of layers, the ratios of the thicknesses of the respective layers, and the like may be different from actual ones.

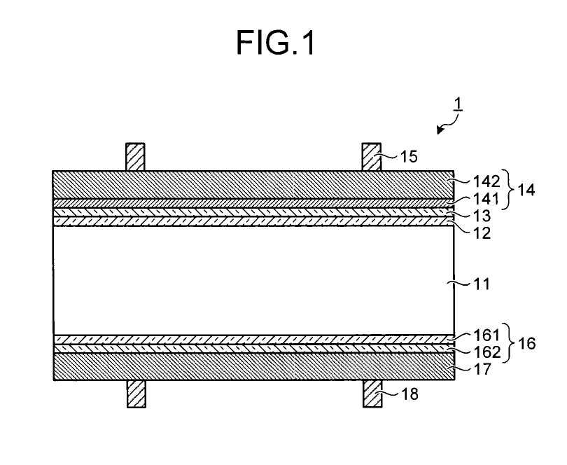

FIG. 1 is a cross-sectional view of the schematic configuration of a photoelectric conversion device according to an embodiment of the present invention. A photoelectric conversion device 1 has a configuration in which a substantially intrinsic i-type amorphous hydrogen-containing semiconductor layer 12 that is a main power generation layer, a second conductivity-type amorphous hydrogen-containing semiconductor layer 13, and a first transparent conductive layer 14 made of a transparent conductive material are stacked on a first surface of a first conductivity-type monocrystalline semiconductor substrate 11 serving as a light receiving surface. That is, the photoelectric conversion device 1 has a heterojunction in which the i-type amorphous hydrogen-containing semiconductor layer 12 is provided between the first conductivity-type monocrystalline semiconductor substrate 11 and the second conductivity-type amorphous hydrogen-containing semiconductor layer 13 in order to improve pn junction characteristics. A comb-like first collecting electrode 15 is formed on the first transparent conductive layer 14.

A BSF (Back Surface Field) layer 16 and a second transparent conductive layer 17 made of a transparent conductive material are stacked on a second surface of the first conductivity-type monocrystalline semiconductor substrate 11 where the second surface opposes the first surface. The BSF layer 16 has a BSF structure in which an i-type amorphous semiconductor layer 161 and a first conductivity-type amorphous semiconductor layer 162 are stacked in this order on the first conductivity-type monocrystalline semiconductor substrate 11. With this structure, carrier recombination on the side of the second transparent conductive layer 17 within the first conductivity-type monocrystalline semiconductor substrate 11 can be prevented. A second collecting electrode 18 is formed on the second transparent conductive layer 17.

According to the present embodiment, the first transparent conductive layer 14, which is provided on the side of the first surface of the first conductivity-type monocrystalline semiconductor substrate 11, includes a hydrogen-diffusion suppression area 141 made of a transparent conductive material that does not substantially contain hydrogen and a hydrogen-containing area 142 made of a transparent conductive material that contains hydrogen. The hydrogen-diffusion suppression area 141 has a function of preventing diffusion of hydrogen from the hydrogen-containing area 142 to the second conductivity-type amorphous hydrogen-containing semiconductor layer 13. As explained later, the hydrogen-diffusion suppression area 141 does not contain hydrogen at the time of forming a film, but hydrogen that diffuses from the hydrogen-containing area 142 is contained in the hydrogen-diffusion suppression area 141 at a subsequent thermal process step. However, as long as the hydrogen content (concentration) of the hydrogen-diffusion suppression area 141 on the side of the second conductivity-type amorphous hydrogen-containing semiconductor layer 13 is lower than the hydrogen content (concentration) of the hydrogen-containing area 142, diffusion of hydrogen to the second conductivity-type amorphous hydrogen-containing semiconductor layer 13 can be suppressed. It suffices that the hydrogen content is equal to or lower than 1 at % in the hydrogen-diffusion suppression area 141 and is higher than 1 at % in the hydrogen-containing area 142. This is because, if the hydrogen content of the hydrogen-diffusion suppression area 141 is higher than 1 at %, diffusion of hydrogen from the hydrogen-containing area 142 to the second conductivity-type amorphous hydrogen-containing semiconductor layer 13 cannot be suppressed sufficiently. Depending on a manufacturing process of the photoelectric conversion device 1, there may be a case where the hydrogen-diffusion suppression area 141 and the hydrogen-containing area 142 diffuse, so that it is difficult to distinguish the hydrogen-diffusion suppression area 141 from the hydrogen-containing area 142. Even in such a case, it suffices that the hydrogen concentration of the first transparent conductive layer 14 on the side of the second conductivity-type amorphous hydrogen-containing semiconductor layer 13 is kept to be lower than that of an area above an area of about 20 nanometers from the bottom surface of the first transparent conductive layer 14. In a case of a configuration that has a hydrogen concentration distribution in which the hydrogen distribution changes gradually within the first transparent conductive layer 14 (a configuration that has a distribution in which the hydrogen concentration is reduced gradually toward the second conductivity-type amorphous hydrogen-containing semiconductor layer 13), an area having a hydrogen content of 1 at % or lower becomes the hydrogen-diffusion suppression area 141, and an area having a hydrogen content of higher than 1 at % becomes the hydrogen-containing area 142.

For example, an n-type monocrystalline silicon (hereinafter, “c-Si”) substrate having a resistivity of approximately 1 Ω·cm and a thickness of several hundreds of micrometers can be used as the first conductivity-type monocrystalline semiconductor substrate 11. A concavity and convexity structure that reduces reflection of light that enters the photoelectric conversion device 1 to enhance the optical confinement effect may be provided on the first and second surfaces of the n-type c-Si substrate. In the concavity and convexity structure, the height from the bottom of a concavity to the top of a convexity is desirably several micrometers to several tens of micrometers.

An i-type amorphous hydrogen-containing silicon (hereinafter, “a-Si:H”) layer, an i-type amorphous hydrogen-containing silicon carbide (hereinafter, “a-SiC:H”) layer, an i-type amorphous hydrogen-containing silicon oxide (hereinafter, “a-SiO:H”) layer, an i-type amorphous hydrogen-containing silicon fluoride (hereinafter, “a-SiF:H”) layer, or an i-type amorphous hydrogen-containing silicon nitride (hereinafter, “a-SiN:H”) layer can be used as the i-type amorphous hydrogen-containing semiconductor layer 12. The i-type amorphous hydrogen-containing semiconductor layer 12 may be formed of a semiconductor material that has a single optical bandgap or a semiconductor material in which the optical bandgap is widened continuously from the side of the first conductivity-type monocrystalline semiconductor substrate 11. Alternatively, the i-type amorphous hydrogen-containing semiconductor layer 12 may be constituted by stacking a plurality of semiconductor materials such that the optical bandgap is widened stepwise from the side of the first conductivity-type monocrystalline semiconductor substrate 11.

To provide a wider optical bandgap than that of i-type a-Si:H, i-type a-SiC:H, i-type a-SiO:H, i-type a-SiF:H, or i-type a-SiN:H can be used. The optical bandgap of the a-Si:H layer can also be widened by increasing the amount of combined hydrogen in the i-type a-Si:H layer.

When the optical bandgap is widened continuously, it suffices that, during film formation of the i-type a-Si:H layer, the concentration of carbon, oxygen, nitrogen, or hydrogen is increased in an inclined manner as being away from the first conductivity-type monocrystalline semiconductor substrate 11. When the optical bandgap is widened stepwise, it suffices that the i-type a-Si:H layer is provided on the side of the first conductivity-type monocrystalline semiconductor substrate 11, and the i-type a-SiC:H layer, the i-type a-SiO:H layer, the i-type a-SiF:H layer, the i-type a-SiN:H layer, or an i-type a-Si:H layer with an increased hydrogen concentration is provided on the i-type a-Si:H layer.

While it suffices that the film thickness of the i-type amorphous hydrogen-containing semiconductor layer 12 is equal to or less than 15 nanometers, in order to increase the electric conductivity of a pn junction, the film thickness is preferably about 5 nanometers. The i-type, first conductivity-type, and second conductivity-type amorphous silicon films used in the present embodiment include not only a complete amorphous film but also a film that has a crystal structure partially in a film such as microcrystalline silicon.

A p-type a-Si:H layer, a p-type a-SiC:H layer, a p-type a-SiO:H layer, a p-type a-SiF:H layer, a p-type a-SiN:H layer, or the like can be used as the second conductivity-type amorphous hydrogen-containing semiconductor layer 13. Similarly to the i-type amorphous hydrogen-containing semiconductor layer 12, the second conductivity-type amorphous hydrogen-containing semiconductor layer 13 may be formed of a semiconductor material that has a single optical bandgap or may be constituted such that the optical bandgap is widened continuously or stepwise from the side of the i-type amorphous hydrogen-containing semiconductor layer 12. By widening the optical bandgap from the side of the i-type amorphous hydrogen-containing semiconductor layer 12, an optical absorption loss of the second conductivity-type amorphous hydrogen-containing semiconductor layer 13 can be reduced.

When the optical bandgap of an area of the second conductivity-type amorphous hydrogen-containing semiconductor layer 13 that contacts the i-type amorphous hydrogen-containing semiconductor layer 12 is narrower than that of an area of the i-type amorphous hydrogen-containing semiconductor layer 12 that contacts the second conductivity-type amorphous hydrogen-containing semiconductor layer 13, the junction characteristics between the second conductivity-type amorphous hydrogen-containing semiconductor layer 13 and the i-type amorphous hydrogen-containing semiconductor layer 12 may be degraded. For this reason, the optical bandgap of the second conductivity-type amorphous hydrogen-containing semiconductor layer 13 at an interface between the second conductivity-type amorphous hydrogen-containing semiconductor layer 13 and the i-type amorphous hydrogen-containing semiconductor layer 12 is preferably equal to or wider than that of the i-type amorphous hydrogen-containing semiconductor layer 12. While it suffices that the film thickness of the second conductivity-type amorphous hydrogen-containing semiconductor layer 13 is equal to or less than 20 nanometers, in order to reduce optical absorption of the second conductivity-type amorphous hydrogen-containing semiconductor layer 13, the film thickness is preferably about 7 nanometers.

An indium oxide (In₂O₃) film that does not substantially contain hydrogen can be used as a film that constitutes the hydrogen-diffusion suppression area 141. Instead of the In₂O₃ film that does not contain hydrogen, a transparent conducting oxide (TCO: Transparent Conducting Oxide) film whose main component is zinc oxide (ZnO) or indium tin oxide (ITO) can also be used. In this case, at least one or more types of elements selected from among well-known dopant materials including aluminum (Al), gallium (Ga), boron (B), nitrogen (N), and the like may be added to ZnO. While ITO has optical absorption in the near-infrared region, the film thickness is equal to or less than 20 nanometers when ITO is used as the hydrogen-diffusion suppression area 141; therefore, an optical absorption loss can be kept lower than that of a transparent conductive layer formed of only ITO as in a conventional case.

A hydrogen-containing indium oxide (hereinafter, “In₂O₃:H”) film can be used as a film that constitutes the hydrogen-containing area 142. The film thickness of the first transparent conductive layer 14 that is constituted by the hydrogen-diffusion suppression area 141 and the hydrogen-containing area 142 is preferably about 70 to 90 nanometers. This is because when it is assumed that the refractive index of air is 1, the refractive index of an In₂O₃ film that is the hydrogen-diffusion suppression area 141 and an In₂O₃:H film that is the hydrogen-containing area 142 is 2, and the refractive index of silicon is 4, with the relationship of film thickness=wavelength/(4×refractive index), a high reflection prevention effect can be obtained in the wavelength region of about 560 to 720 nanometers.

A layer made of at least one or more types of elements selected from among silver (Ag), Al, gold (Au), copper (Cu), nickel (Ni), rhodium (Rh), platinum (Pt), palladium (Pr), chromium (Cr), titanium (Ti), molybdenum (Mo), and the like that have high reflectivity and conductivity, or alloys thereof can be used as the comb-like first collecting electrode 15.

An i-type a-Si:H layer, an i-type a-SiC:H layer, an i-type a-SiO:H layer, an i-type a-SiF:H layer, or an i-type a-SiN:H layer can be used as the i-type amorphous semiconductor layer 161. Further, an n-type a-Si:H layer, an n-type a-SiC:H layer, an n-type a-SiO:H layer, an n-type a-SiF:H layer, or an n-type a-SiN:H layer can be used as the first conductivity-type amorphous semiconductor layer 162. For example, the film thickness of the i-type amorphous semiconductor layer 161 can be 5 nanometers. For example, the film thickness of the first conductivity-type amorphous semiconductor layer 162 can be 20 nanometers. Similarly to the i-type amorphous hydrogen-containing semiconductor layer 12, the i-type amorphous semiconductor layer 161 and the first conductivity-type amorphous semiconductor layer 162 may be formed of a semiconductor material that has a single optical bandgap or may be configured such that the optical bandgap is widened continuously or stepwise toward the side of the first conductivity-type monocrystalline semiconductor substrate 11.

Because the second transparent conductive layer 17 is formed on the back surface of the first conductivity-type monocrystalline semiconductor substrate 11 that is opposite to the light receiving surface thereof, it suffices that the second transparent conductive layer 17 is transparent to light that has transmitted through the first conductivity-type monocrystalline semiconductor substrate 11. The second transparent conductive layer 17 may be a film made of a transparent conductive material having an optical bandgap narrower than those of the hydrogen-diffusion suppression area 141 and the hydrogen-containing area 142. A TCO film that contains at least one of ZnO, ITO, tin oxide (SnO₂), and In₂O₃ can be used as the second transparent conductive layer 17. Alternatively, the second transparent conductive layer 17 may be formed of a translucent film obtained by adding at least one or more types of elements selected from among dopant materials including Al, Ga, B, hydrogen (H), fluorine (F), silicon (Si), magnesium (Mg), Ti, Mo, tin (Sn), and the like to these transparent conductive material films. For example, the film thickness of the second transparent conductive layer 17 can be 100 nanometers. These specific materials for the second transparent conductive layer 17 are not particularly limited, and materials can be appropriately selected and used from among well-known materials. The second transparent conductive layer 17 may have a surface texture having a concavity and a convexity formed on a surface thereof. This surface texture has a function of scattering incident light to increase the light use efficiency of the first conductivity-type monocrystalline semiconductor substrate 11 serving as a main power generation layer.

A layer made of at least one or more types of elements selected from among Ag, Al, Au, Cu, Ni, Rh, Pt, Pr, Cr, Ti, Mo, and the like that have high reflectivity and conductivity, or alloys thereof can be used as the second collecting electrode 18. While the second collecting electrode 18 is formed in a comb shape in FIG. 1, the second collecting electrode 18 may be formed so as to cover the entire surface of the second transparent conductive layer 17. As a result, the reflectivity of the second collecting electrode 18 can be increased and the light use efficiency of the first conductivity-type monocrystalline semiconductor substrate 11 can be improved.

While examples of materials in which the first conductivity-type is an n-type and the second conductivity-type is a p-type have been explained above, conversely, the first conductivity-type may be the p-type and the second conductivity-type may be the n-type in the materials explained above.

An outline of an operation of the photoelectric conversion device 1 with such a configuration is explained. An explanation is given assuming that the first conductivity-type is the n-type and the second conductivity-type is the p-type in the respective layers of FIG. 1. In the photoelectric conversion device 1, when sunlight enters from the side of the first surface, carriers are generated in the first conductivity-type (n-type) monocrystalline semiconductor substrate 11. Electrons and holes serving as carriers are separated from each other by the internal electric field generated by the first conductivity-type (n-type) monocrystalline semiconductor substrate 11 and the second conductivity-type (p-type) amorphous hydrogen-containing semiconductor layer 13. The electrons move toward the first conductivity-type (n-type) monocrystalline semiconductor substrate 11, pass through the BSF layer 16, and reach the second transparent conductive layer 17. The holes move toward the second conductivity-type (p-type) amorphous hydrogen-containing semiconductor layer 13 to reach the first transparent conductive layer 14. As a result, the first collecting electrode 15 becomes a positive electrode and the second collecting electrode 18 becomes a negative electrode, and power is taken out to the outside.

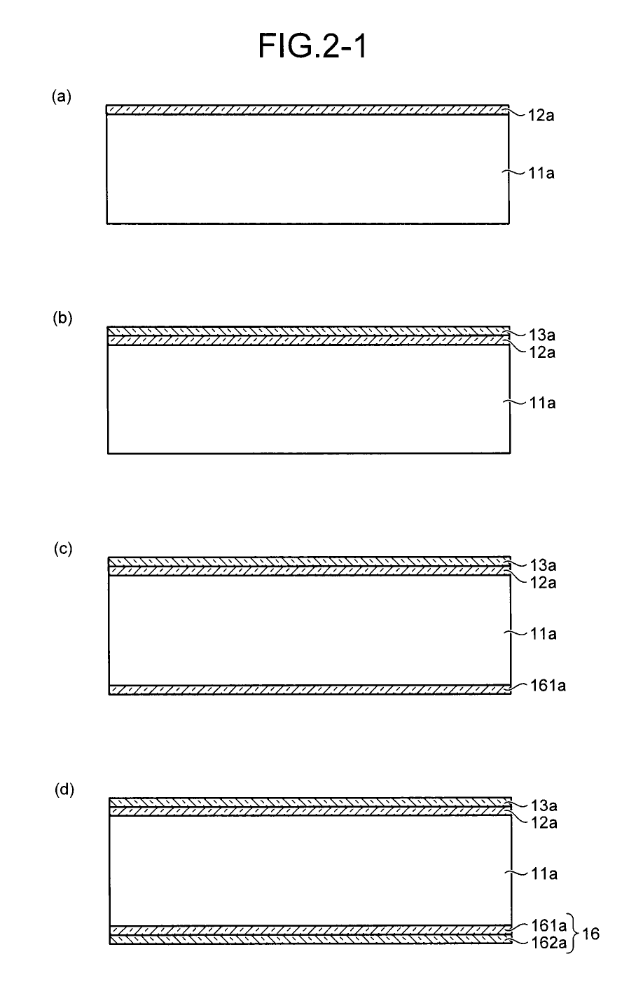

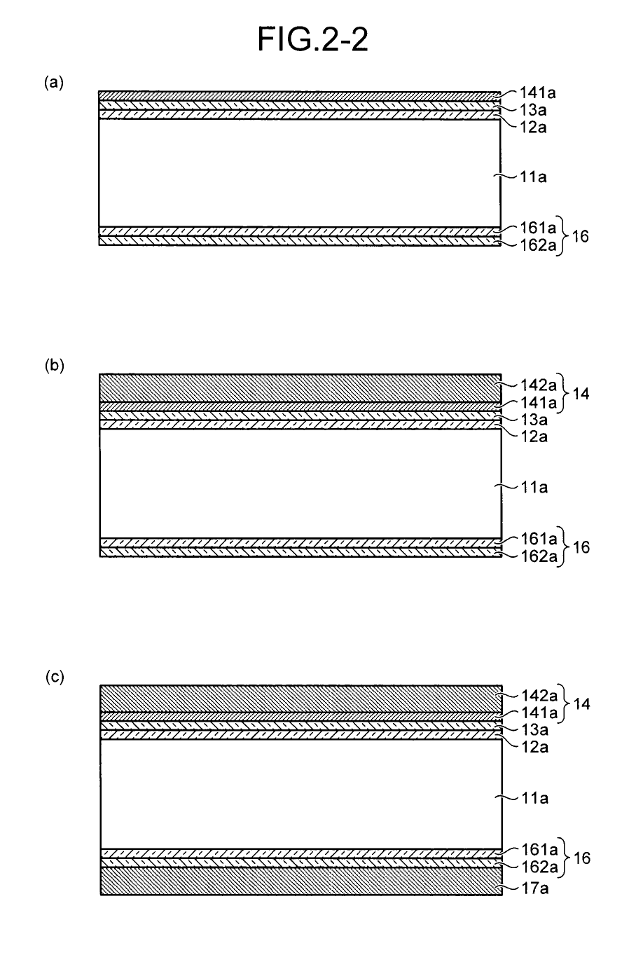

Next, a manufacturing method of the photoelectric conversion device 1 with such a configuration is explained. FIGS. 2-1 to 2-2 are schematic cross-sectional views of an example of a procedure of the manufacturing method of the photoelectric conversion device according to the present embodiment. An n-type c-Si substrate 11a that has a (100) surface, a resistivity of approximately 1 Ω·cm, and a thickness of approximately 200 micrometers is prepared first as the first conductivity-type monocrystalline semiconductor substrate 11. A pyramid-like concavity and convexity structure having a height of several micrometers to several tens of micrometers is then formed on the first and second surfaces. The pyramid-like concavity and convexity structure can be formed by, for example, anisotropic etching using an alkaline solution, such as sodium hydroxide (NaOH) and potassium hydroxide (KOH). While the degree of anisotropy depends on the composition of the alkaline solution, the etching rate in the <100> direction is higher than that in the <111> direction. Accordingly, when the n-type c-Si substrate 11a that has the (100) surface is etched, a (111) surface with a low etching rate remains.

Next, the n-type c-Si substrate 11a is washed, moved into a first vacuum chamber, and is heated under vacuum at a substrate temperature of 200° C. or lower to remove moisture on the substrate surfaces. For example, a heating process is performed at a substrate temperature of 170° C. Hydrogen (H₂) gas is then introduced in the first vacuum chamber and cleaning is performed on the first surface of the n-type c-Si substrate 11a by plasma discharge.

Next, as shown in FIG. 2-1(a), silane (SiH₄) gas and H₂ gas are introduced in the first vacuum chamber, the substrate temperature is kept at 170° C., and an i-type a-Si:H layer 12a serving as the i-type amorphous hydrogen-containing semiconductor layer 12 is formed on the first surface of the n-type c-Si substrate 11a by plasma-enhanced chemical vapor deposition (CVD: Chemical Vapor Deposition). For example, the film thickness of the i-type a-Si:H layer 12a can be 5 nanometers. As explained above, the i-type a-Si:H layer 12a may be formed of a material that has a single optical bandgap or a material whose optical bandgap is widened continuously or stepwise from the side of the n-type c-Si substrate 11a.

Thereafter, as shown in FIG. 2-1(b), the n-type c-Si substrate 11a is moved into a second vacuum chamber, and SiH₄ gas, H₂ gas, and diborane (B₂H₆) gas are introduced in the second vacuum chamber to form a p-type a-Si:H layer 13a serving as the second conductivity-type amorphous hydrogen-containing semiconductor layer 13 on the i-type a-Si:H layer 12a by plasma CVD. At this time, the substrate temperature is equal to or lower than 170° C. and the flow rate of the B₂H₆ gas is about 1% of the flow rate of the SiH₄ gas. In this case, the substrate temperature can be increased to 170° C. and the film thickness of the p-type a-Si:H layer 13a can be, for example, 7 nanometers. As explained above, the p-type a-Si:H layer 13a may be formed of a material that has a single optical bandgap or a material whose optical bandgap is widened continuously or stepwise from the side of the i-type a-Si:H layer 12a.

Next, the n-type c-Si substrate 11a is moved into a third vacuum chamber, H₂ gas is introduced in the third vacuum chamber, and cleaning is performed on the second surface of the n-type c-Si substrate 11a at a substrate temperature of 170° C. by plasma discharge.

Thereafter, as shown in FIG. 2-1(c), SiH₄ gas and H₂ gas are introduced in the third vacuum chamber, the substrate temperature is kept at 170° C., and similarly to the i-type a-Si:H layer 12a, an i-type a-Si:H layer 161a serving as the i-type amorphous semiconductor layer 161 is formed on the second surface of the n-type c-Si substrate 11a by plasma CVD. Then, as shown in FIG. 2-1(d), the n-type c-Si substrate 11a is moved into a fourth vacuum chamber, SiH₄ gas, H₂ gas, and phosphine (PH₃) gas are introduced in the fourth vacuum chamber, the substrate temperature is kept at 170° C., and an n-type a-Si:H layer 162a serving as the first conductivity-type amorphous semiconductor layer 162 is formed on the i-type a-Si:H layer 161a by plasma CVD. The thickness of the i-type a-Si:H layer 12a can be 5 nanometers and the thickness of the n-type a-Si:H layer 162a can be 20 nanometers. At this point, the i-type a-Si:H layer 161a and the n-type a-Si:H layer 162a may also be formed of a material that has a single optical bandgap or a material whose optical bandgap is widened continuously or stepwise toward the n-type c-Si substrate 11a. The BSF layer 16 is formed of the i-type a-Si:H layer 161a and the n-type a-Si:H layer 162a.

Next, the first transparent conductive layer 14 in which an In₂O₃ film 141a that does not substantially contain hydrogen and serves as the hydrogen-diffusion suppression area 141 and an In₂O₃:H film 142a serving as the hydrogen-containing area 142 are stacked is formed on the p-type a-Si:H layer 13a. The In₂O₃ film 141a and the In₂O₃:H film 142a can be formed by sputtering using an In₂O₃ target.

When the In₂O₃ film 141a and the In₂O₃:H film 142a are formed at a process temperature of 200° C. or lower, films with higher mobility can be obtained by a method of depositing amorphous films by sputtering at a low temperature, for example, about a room temperature and then heating these amorphous films to crystallize the films (solid-phase crystallization), as compared to, for example, a method of forming films by sputtering at a substrate temperature of about 170° C. Therefore, a method of forming the In₂O₃ film 141a and the In₂O₃:H film 142a by stacking amorphous films of In₂O₃ and In₂O₃:H by sputtering at a substrate temperature of about a room temperature and then heating these films is explained. An In₂O₃ film that does not substantially contain hydrogen used in the present embodiment means that hydrogen is not added intentionally to a film as a dopant, and also includes an In₂O₃ film in which a small amount of hydrogen is taken in a film because of hydrogen and moisture remaining in a film forming chamber. At this time, as the hydrogen content of the In₂O₃ film is reduced, the crystallinity thereof tends to be increased. Further, as the crystallinity is increased, the film tends to have a higher barrier performance against hydrogen diffusion. That is, by increasing the crystallinity of the In₂O₃ film 141a more than that of the In₂O₃:H film 142a, a hydrogen diffusion suppression effect of the In₂O₃ film 141a can be enhanced. The crystallinity is the ratio of a crystalline part in a film that has a crystalline part and an amorphous part and can be determined by, for example, XRD (X-ray diffraction).

The hydrogen content of the In₂O₃ film 141a and the In₂O₃:H film 142a can be estimated from the results of thermal desorption spectroscopy (TDS: Thermal Desorption Spectroscopy) or secondary ion mass spectrometry (SIMS: Secondary Ion Mass Spectrometry). A case of using the TDS method is described herein. To eliminate influences of desorption gas from the i-type a-Si:H layer 12a and the p-type a-Si:H layer 13a, the In₂O₃ film 141a or the In₂O₃:H film 142a are deposited on a Si substrate having an oxide film formed thereon, and then the hydrogen content is estimated. As a result, in a case of the In₂O₃ film 141a that does not substantially contain hydrogen according to the present embodiment, the hydrogen concentration estimated by the method explained above is equal to or lower than 1 at %. The hydrogen concentration of the In₂O₃:H film 142a is higher than 1 at %.

A method of forming the In₂O₃ film 141a is explained first. As shown in FIG. 2-2(a), argon (Ar) gas is introduced in a fifth vacuum chamber, and the In₂O₃ film 141a is deposited on the p-type a-Si:H layer 13a by sputtering at a substrate temperature of about a room temperature. About a room temperature used in the present embodiment means that heating is not performed intentionally from the outside, and a case where the substrate temperature rises to about 70° C. or lower due to plasma during sputtering is also included. By introducing oxygen (O₂) gas having a flow rate of about 0.1 to 1% of the flow rate of the Ar gas in the fifth vacuum chamber, an oxygen loss of the In₂O₃ film 141a can be suppressed and the transmittance and mobility of the In₂O₃ film 141a can be improved. It suffices that the film thickness of the In₂O₃ film 141a is 1 to 20 nanometers. With such a film thicknesses, it is possible to suppress diffusion of hydrogen from the In₂O₃:H film 142a to the p-type a-Si:H layer 13a in a subsequent process.

The film thickness of the In₂O₃ film 141a according to the present embodiment means the thickness of a film that is deposited on the p-type a-Si:H layer 13a by sputtering film formation, that is, the film thickness immediately after deposition, and does not mean the film thickness of the In₂O₃ film 141a that is present in the photoelectric conversion device 1 after all the manufacturing processes are completed (hereinafter, “after production”). That is, in processes after the In₂O₃ film 141a is deposited, there may be a case where hydrogen in a sputtering film formation atmosphere of the In₂O₃:H film 142a that contains hydrogen and in the film diffuses to the In₂O₃ film 141a, and a portion serving as the In₂O₃ film 141a is not present in the photoelectric conversion device 1 after production. Alternatively, there may be a case where a portion in which the hydrogen content of the In₂O₃ film 141a is reduced in a graded manner (in an inclined manner) from the side of the In₂O₃:H film 142a toward the side of the p-type a-Si:H layer 13a is included. In the In₂O₃ film 141a of the photoelectric conversion device 1 after production, when the hydrogen content of the In₂O₃ film 141a on the side of the p-type a-Si:H layer 13a is lower than that of the In₂O₃:H film 142a, an effect of suppressing diffusion of hydrogen to the p-type a-Si:H layer 13a can be obtained.

Next, a method of forming the In₂O₃:H film 142a is explained. As shown in FIG. 2-2(b), Ar gas, O₂ gas, and H₂ gas are introduced in the fifth vacuum chamber, the substrate temperature is kept at about a room temperature, and the In₂O₃:H film 142a is deposited on the In₂O₃ film 141a by sputtering. At this time, instead of the H₂ gas, water vapor (H₂O) gas that is vaporized by bubbling using Ar gas may be introduced. The In₂O₃:H film 142a is preferably formed continuously after the In₂O₃ film 141a is formed, without breaking vacuum. Alternatively, the In₂O₃:H film 142a may be formed by introducing H₂ gas while plasma discharge at the time of film formation of the In₂O₃ film 141a is kept. The total film thickness of the In₂O₃ film 141a and the In₂O₃:H film 142a can be about 70 to 90 nanometers.

At this time, a small amount, for example, about 0.1 to 1 wt % of SnO₂ may be added to a target that is used for sputtering film formation of the In₂O₃ film 141a and the In₂O₃:H film 142a. Accordingly, the formed In₂O₃ film 141a and In₂O₃:H film 142a contain about 0.1 to 1 wt % of SnO₂, and thus the carrier concentration can be increased while the mobility of the In₂O₃ film 141a and the In₂O₃:H film 142a is kept to be a relatively high value, so that the conductivity is increased. By adding a small amount of SnO₂ to the target, the density of the target is increased. As a result, the amount of deposited foreign matters (nodules) on a surface of the target caused by sputtering can be reduced, and in-plane uniformity of the film quality and film thickness of deposited films can also be improved. When the amount of SnO₂ is less than 0.1 wt %, a carrier concentration that does not cause an optical absorption loss while the mobility is kept to be a relatively high value cannot be obtained. When the amount of SnO₂ is more than 1 wt %, there may be an optical absorption loss caused by carriers. Therefore, it is desirable that the added amount of SnO₂ is 0.1 to 1 wt %.

Further, at the time of sputtering film formation of the In₂O₃ film 141a and the In₂O₃:H film 142a, nitrogen (N₂) gas may be introduced in the fifth vacuum chamber together with Ar, O₂, and H₂ gas mentioned above. By additionally introducing N₂ gas, the reproducibility of the film quality and film thickness of the In₂O₃ film 141a and the In₂O₃:H film 142a can be improved.

Instead of the In₂O₃ film 141a, TCO whose main component is ZnO or ITO may be used as the hydrogen-diffusion suppression area 141, and at least one or more types of elements selected from among well-known dopant materials including Al, Ga, B, N, and the like may be added to ZnO. TCO whose main component is ZnO or ITO can be produced by various methods, such as sputtering, electron beam deposition, atomic layer deposition, atmospheric-pressure CVD, low-pressure CVD, metal organic CVD (MOCVD: Metal Organic CVD), sol-gel, printing, spraying, and the like.

Next, as shown in FIG. 2-2(c), the n-type c-Si substrate 11a is moved into a sixth vacuum chamber, and a ZnO film 17a serving as the second transparent conductive layer 17 is formed on the n-type a-Si:H layer 162a. The ZnO film 17a can be produced by various methods, such as sputtering, electron beam deposition, atomic layer deposition, CVD, low-pressure CVD, MOCVD, sol-gel, printing, spraying, and the like. The film thickness of the ZnO film 17a can be, for example, 100 nanometers.

Thereafter, the n-type c-Si substrate 11a is moved into a seventh vacuum chamber and heated at a temperature of 200° C. or lower. At this time, inert gas, such as Ar gas and N₂ gas, may be introduced in the seventh vacuum chamber. By heating the n-type c-Si substrate 11a at a temperature of 220° C. or lower, a passivation effect between the n-type c-Si substrate 11a and the i-type a-Si:H layer 12a and between the n-type c-Si substrate lie and the i-type a-Si:H layer 161a can be enhanced, and a mobility enhancement effect due to crystallization of the In₂O₃ film 141a and the In₂O₃:H film 142a can be obtained. As the substrate temperature increases, crystallization of the In₂O₃ film 141a and the In₂O₃:H film 142a is accelerated and the mobility is enhanced. However, when the substrate temperature is increased to about 250° C., depending on film formation conditions of a-Si:H layers, a Si—H bond in amorphous silicon is broken and hydrogen in the amorphous silicon is discharged, so that the number of defects in the amorphous silicon increases. As a result, the passivation effect of the n-type c-Si substrate 11a is reduced and carrier recombination on a surface of the n-type c-Si substrate 11a is increased. In the p-type a-Si:H layer 13a, hydrogen that is discharged from the i-type a-Si:H layer 12a between the n-type c-Si substrate 11a and the p-type a-Si:H layer 13a is diffused to the p-type a-Si:H layer 13a, so that B serving as a dopant for the p-type a-Si:H layer 13a is inactivated and the internal electric field of the photoelectric conversion device 1 may be reduced. Because of these reasons, according to the present embodiment, heating is performed at a substrate temperature of 190° C.

The first collecting electrode 15 is then formed on the In₂O₃:H film 142a and the second collecting electrode 18 is formed on the ZnO film 17a. The first collecting electrode 15 and the second collecting electrode 18 can be produced by applying a conductive paste, such as a silver paste, by printing to be in a comb shape and then sintering the paste at a substrate temperature of 200° C. for 90 minutes. The second collecting electrode 18 may be formed of a layer made of at least one or more types of elements selected from among Ag, Al, Au, Cu, Ni, Rh, Pt, Pr, Cr, Ti, Mo, and the like that have high reflectivity and conductivity, or alloys thereof, and may be formed so as to cover the entire surface of the ZnO film 17a. In this manner, the photoelectric conversion device 1 with the configuration shown in FIG. 1 can be obtained.

According to the present embodiment, the hydrogen-diffusion suppression area 141 that is formed of an In₂O₃ film that does not substantially contain hydrogen or a TCO film whose main component is ZnO or ITO is interposed between the second conductivity-type amorphous hydrogen-containing semiconductor layer 13 and the hydrogen-containing area 142 of the first transparent conductive layer 14. Therefore, it is possible to suppress diffusion of hydrogen radicals present in a film formation chamber atmosphere of the hydrogen-containing area 142 or hydrogen in the hydrogen-containing area 142 to the second conductivity-type amorphous hydrogen-containing semiconductor layer 13. As a result, in the process during or after film formation of the hydrogen-containing area 142, a decrease in the activation rate of a dopant for the second conductivity-type amorphous hydrogen-containing semiconductor layer 13 is suppressed, and occurrence of a bad contact of the hydrogen-containing area 142 and the second conductivity-type amorphous hydrogen-containing semiconductor layer 13 can be prevented. Accordingly, degradation in output characteristics of a solar cell can be suppressed and a photoelectric conversion device with high power generation efficiency can be realized.

While the photoelectric conversion device 1 including one semiconductor photoelectric conversion layer has been explained herein as an example, the present invention is not limited thereto, and arbitrary embodiments can be made without departing from the scope of the invention. That is, the present invention is not limited to a photoelectric conversion device that has a heterojunction of crystalline silicon and amorphous silicon, and can be applied also to, for example, a thin-film photoelectric conversion device that has a configuration in which a transparent conductive layer that has a hydrogen-containing area is formed on a semiconductor layer of a predetermined conductivity-type.

By providing a plurality of the photoelectric conversion devices 1 that has the configuration explained in the above embodiment as photoelectric conversion cells and electrically connecting adjacent photoelectric conversion cells in series or in parallel, a photoelectric conversion module that has a high optical confinement effect and excellent photoelectric conversion efficiency can be realized.

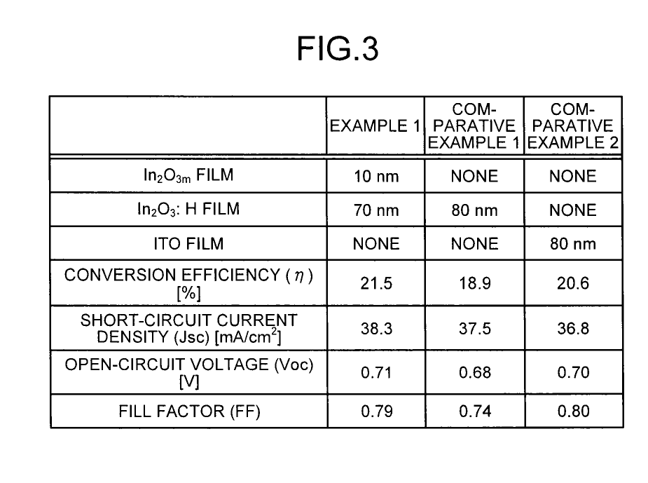

An example of a photoelectric conversion cell with the configuration as explained in the present embodiment is explained with comparative examples. FIG. 3 is a diagram of an example of the states of respective first transparent conductive layers of photoelectric conversion cells according to an Example and Comparative examples and the evaluation results thereof.

### Example 1

Example 1 explains a photoelectric conversion cell in which the hydrogen-diffusion suppression area 141 formed of a transparent conductive film that does not substantially contain hydrogen is present.

<Manufacturing Method>

As the first conductivity-type monocrystalline semiconductor substrate 11, an n-type c-Si substrate that has a resistivity of approximately 1 Ω·cm and a thickness of approximately 200 micrometers, and includes a (100) surface is used. After the n-type c-Si substrate is washed, pyramid-like concavities and convexities having a height of several micrometers to several tens of micrometers are formed on the surface of the n-type c-Si substrate by etching using an alkaline solution. Next, the n-type c-Si substrate 11a is introduced in a vacuum chamber and heated at 200° C. to remove moisture adhered to the substrate surface. Hydrogen gas is then introduced in the vacuum chamber and plasma discharge is performed to clean the substrate surface. Thereafter, the substrate temperature is set to be approximately 150° C., SiH₄ gas and H₂ gas are introduced in the vacuum chamber, and an i-type a-Si:H layer having a thickness of approximately 5 nanometers is formed by RF plasma CVD. Then, SiH₄ gas, H₂ gas, and B₂H₆ gas are introduced in the vacuum chamber, and a p-type a-Si:H layer having a thickness of approximately 5 nanometers is formed as the second conductivity-type amorphous hydrogen-containing semiconductor layer 13.

Next, an In₂O₃ film that has a thickness of approximately 10 nanometers, contains approximately 0.8 at % of hydrogen, and does not substantially contain hydrogen is formed on the p-type a-Si:H layer as the hydrogen-diffusion suppression area 141 by sputtering. On the In₂O₃ film, an In₂O₃:H film that has a film thickness of approximately 70 nanometers and contains approximately 2.5 at % of hydrogen is formed as the hydrogen-containing area 142 by sputtering. The In₂O₃ film and the In₂O₃:H film are formed continuously at a substrate temperature of about a room temperature by using the same In₂O₃ sputtering target and sputtering device, according to the presence or absence of introduced hydrogen gas.

Thereafter, on the opposite surface of the n-type c-Si substrate, an i-type a-Si:H layer that has a thickness of approximately 5 nanometers and serves as the i-type amorphous semiconductor layer 161 is formed by plasma CVD, and continuously, while PH₃ gas is introduced as doping gas, an n-type a-Si:H layer that has a thickness of approximately 20 nanometers and serves as the first conductivity-type amorphous semiconductor layer 162 is formed by plasma CVD. Next, an In₂O₃ (ITO) film having a thickness of approximately 100 nanometers and having SnO₂ added thereto is formed on the n-type a-Si:H layer as the second transparent conductive layer 17 by sputtering at a substrate temperature of approximately 200° C. Ar gas is then introduced in the vacuum chamber and a heating process is performed at a substrate temperature of approximately 200° C. for about two hours. The comb-like first and second collecting electrodes 15 and 18 made of a silver paste are formed on predetermined areas of the top surfaces of the In₂O₃:H film and the ITO film by screen printing, thereby producing a photoelectric conversion cell.

<Evaluation Method>

Pseudo-sunlight is radiated onto the produced photoelectric conversion cell from the side of the first collecting electrode 15 by a solar simulator to measure current-voltage characteristics, and conversion efficiency (η), short-circuit current density (Jsc), open-circuit voltage (Voc), and fill factor (FF) are calculated.

<Evaluation Result>

As a result of the evaluation of the cell characteristics of the photoelectric conversion cell produced in the Example 1, as shown in FIG. 3, the conversion efficiency is 21.5%, the short-circuit current density is 38.3 mA/cm², the open-circuit voltage is 0.71 volts, and the fill factor is 0.79.

### Comparative Example 1

Comparative example 1 explains a photoelectric conversion cell in which the hydrogen-diffusion suppression area 141 is not present.

<Manufacturing Method and Evaluation Method>

A photoelectric conversion cell according to the Comparative example 1 is different from the photoelectric conversion cell according to the Example 1 only in that the hydrogen-diffusion suppression area 141 is not present. That is, according to the photoelectric conversion cell of the Comparative example 1, a hydrogen-diffusion suppression area is not formed on a p-type a-Si:H layer, and an In₂O₃:H film that has a film thickness of approximately 80 nanometers and contains approximately 2.5 at % of hydrogen is formed as the hydrogen-containing area 142. The photoelectric conversion cell according to the Comparative example 1 is produced in the same conditions expect for the production conditions of an In₂O₃ film and an In₂O₃:H film in the production conditions of the photoelectric conversion cell according to the Example 1. An evaluation method is also executed in the same conditions as those of the Example 1.

<Evaluation Result>

As a result of the evaluation of the cell characteristics of the photoelectric conversion cell produced in the Comparative example 1, as shown in FIG. 3, the conversion efficiency (η) is 18.9%, the short-circuit current density (Jsc) is 37.5 mA/cm², the open-circuit voltage (Voc) is 0.68 volts, and the fill factor is 0.74.

### Comparative Example 2

Comparative example 2 explains a conventional photoelectric conversion cell that uses an ITO film as a transparent conductive film layer on the first surface side of the n-type c-Si substrate 11a.

<Manufacturing Method and Evaluation Method>

A photoelectric conversion cell according to the Comparative example 2 is different from the photoelectric conversion cell according to the Comparative example 1 only in that an ITO film is formed instead of the In₂O₃:H film produced in the photoelectric conversion cell according to the Comparative example 1. That is, according to the photoelectric conversion cell of the Comparative example 2, an ITO film having a film thickness of approximately 80 nanometers is formed on a p-type a-Si:H layer as the hydrogen-containing area 142 at a substrate temperature of approximately 200° C. by sputtering using a target having 10 wt % of SnO₂ added to In₂O₃. The photoelectric conversion cell according to the Comparative example 2 is produced in the same conditions expect for the production conditions of an In₂O₃:H film in the production conditions of the photoelectric conversion cell according to the Comparative example 1. An evaluation method is also executed in the same conditions as those of the Example 1.

<Evaluation Result>

As a result of the evaluation of the cell characteristics of the photoelectric conversion cell produced in the Comparative example 2, as shown in FIG. 3, the conversion efficiency (η) is 20.6%, the short-circuit current density (Jsc) is 36.8 mA/cm², the open-circuit voltage (Voc) is 0.70 volts, and the fill factor is 0.80.

As in the Example 1, it is found that by interposing an In₂O₃ film between a p-type a-Si:H layer and an In₂O₃:H film, the internal electric field increases, excellent contact characteristics between the p-type a-Si:H layer and the In₂O₃:H film are provided, and the optical transparency in the near-infrared region is improved, so that a photoelectric conversion cell with a higher efficiency than those of the Comparative examples 1 and 2 can be produced.

### REFERENCE SIGNS LIST

1 photoelectric conversion device
11 first conductivity-type monocrystalline semiconductor substrate
11a n-type c-Si substrate
12 i-type amorphous hydrogen-containing semiconductor layer
12a, 161a i-type a-Si:H layer
13 second conductivity-type amorphous hydrogen-containing semiconductor layer
13a p-type a-Si:H layer
14 first transparent conductive layer
15, 18 collecting electrode
16 BSF layer
17 second transparent conductive layer
17a ZnO film
141 hydrogen-diffusion suppression area
141a In₂O₃ film
142 hydrogen-containing area
142a In₂O₃:H film
161 i-type amorphous semiconductor layer
162 first conductivity-type amorphous semiconductor layer
162a n-type a-Si:H layer

1: A photoelectric conversion device in which a substantially intrinsic semiconductor layer, a p-type semiconductor layer, and a transparent conductive layer are stacked in this order on a first surface of an n-type semiconductor substrate that generates a photogenerated carrier by receiving light, wherein
the transparent conductive layer includes a hydrogen-containing area formed of a transparent conductive material that contains hydrogen and a hydrogen-diffusion suppression area that is present on a side of the p-type semiconductor layer with respect to the hydrogen-containing area and that is formed of a transparent conductive material that does not substantially contain hydrogen,
the hydrogen-diffusion suppression area has a hydrogen concentration distribution in which a hydrogen content on a side of the p-type semiconductor layer is lower than a hydrogen content on a side of the hydrogen-containing area,
a hydrogen concentration of the hydrogen-diffusion suppression area is equal to or lower than 1 at %, and
a hydrogen concentration of the hydrogen-containing area is higher than 1 at %.

2. (canceled)

3: A photoelectric conversion device in which a substantially intrinsic semiconductor layer, a p-type semiconductor layer, and a transparent conductive layer are stacked in this order on a first surface of an n-type semiconductor substrate that generates a photogenerated carrier by receiving light, wherein
the transparent conductive layer includes a hydrogen-containing area formed of a transparent conductive material that contains hydrogen and a hydrogen-diffusion suppression area that is present on a side of the p-type semiconductor layer with respect to the hydrogen-containing area and that is formed of a transparent conductive material that does not substantially contain hydrogen,
the hydrogen-diffusion suppression area has a hydrogen concentration distribution in which a hydrogen content on a side of the p-type semiconductor layer is lower than a hydrogen content on a side of the hydrogen-containing area, and
crystallinity of the hydrogen-diffusion suppression area is higher than crystallinity of the hydrogen-containing area.

4: A photoelectric conversion device in which a substantially intrinsic semiconductor layer, a p-type semiconductor layer, and a transparent conductive layer are stacked in this order on a first surface of an n-type semiconductor substrate that generates a photogenerated carrier by receiving light, wherein
the transparent conductive layer includes a hydrogen-containing area formed of a transparent conductive material that contains hydrogen and a hydrogen-diffusion suppression area that is present on a side of the p-type semiconductor layer with respect to the hydrogen-containing area and that is formed of a transparent conductive material that does not substantially contain hydrogen,
the hydrogen-diffusion suppression area has a hydrogen concentration distribution in which a hydrogen content on a side of the p-type semiconductor layer is lower than a hydrogen content on a side of the hydrogen-containing area, and
the hydrogen-containing area and the hydrogen-diffusion suppression area are formed of indium oxide or an indium oxide film that contains 0.1 wt % or more and 1 wt % or less of tin oxide.

5-8. (canceled)

9: A manufacturing method of a photoelectric conversion device by stacking a substantially intrinsic semiconductor layer, a p-type semiconductor layer, and a transparent conductive layer in this order on an n-type semiconductor substrate that generates a photogenerated carrier by receiving light, the method comprising:
a manufacturing of the transparent conductive layer including forming a first transparent conductive material layer on the p-type semiconductor layer without adding hydrogen gas and thereafter forming a second transparent conductive material layer on the first transparent conductive material layer while adding hydrogen gas.

10: The manufacturing method of a photoelectric conversion device according to claim 9, wherein
the manufacturing of the transparent conductive layer includes continuously depositing and forming the first transparent conductive material layer that does not substantially contain hydrogen and the second transparent conductive material layer that contains hydrogen by changing a type and a flow ratio of introduced gas at a time of film formation by sputtering using a same target.

11. (canceled)

12: The manufacturing method of a photoelectric conversion device according to claim 9, wherein the manufacturing of the transparent conductive layer includes stacking the first transparent conductive material layer whose main component is indium oxide and the second transparent conductive material layer whose main component is indium oxide.
